(19) United States
(12) Patent Application Publication
(10) Pub. No.: US 2002/0098683 A1
(43) Pub. Date: Jul. 25, 2002

(54) Semiconductor device manufacturing method using metal silicide reaction after ion implantation in silicon wiring

(75) Inventor: Tamihide Yasumoto, Kasugai (JP)

Correspondence Address: ARMSTRONG,WESTERMAN & HATTORI, LLP, 1725 K STREET, NW., SUITE 1000, WASHINGTON, DC, 20006, US

(73) Assignee: FUJITSU LIMITED, Kawasaki (JP)

(21) Appl. No.: 09/995,575

(22) Filed: Nov. 29, 2001

(30) Foreign Application Priority Data
Jan. 22, 2001 (JP) 2001-013101

(51) Int. Cl. H01L 21/44; H01L 21/4763

(52) U.S. Cl. 438/630

(57) ABSTRACT

A wiring of silicon is formed on a surface of a semiconductor substrate. Part of the wiring is covered with a resist pattern. Ion implantation is conducted on the substrate using the resist pattern as a mask and then the resist pattern is removed. An upper section of the wiring with a thickness of at least 5 nm is removed to minimize thickness of the wiring. Reaction is caused between a surface section of the wiring of which thickness is thus reduced and a metal which reacts with silicon to form suicide to thereby form a metal silicide film on a surface of the wiring. Resistance of the wiring can be reduced with good reproducibility.

This application is based on Japanese Patent Application 2001-013101, filed on Jan. 22, 2001, the entire contents of which are incorporated herein by reference.

### BACKGROUND OF THE INVENTION

A) Field of the Invention

The present invention relates to a semiconductor device manufacturing method, and in particular, to a method of manufacturing a semiconductor device in which ion implantation is performed on part of silicon wiring covered with a resist pattern and then a metal silicide layer is formed on the wiring to thereby lowering resistance thereof.

B) Description of the Related Art

To lower resistance of silicon wiring, there has been known a technique to form a metal silicide film on a surface of the wiring. The metal silicide film is formed as follows. A metallic layer of a metal which forms silicide with silicon is deposited on a surface of silicon wiring, and then a chemical reaction takes place between the silicon wiring and the metallic layer to resultantly form a metal silicide film. Before the metallic layer is deposited, the surface of the silicon wiring is ordinarily cleaned. A natural oxide film formed on the surface of the silicon wiring and impurities fixed on the surface thereof are removed, for example, by wet cleaning.

It has been found as a result of an attempt to lower resistance of the silicon wiring in the prior art technique that there remain locations or regions thereof in which resistance is not fully lowered.

### SUMMARY OF THE INVENTION

It is an object of the present invention to provide a method of manufacturing a semiconductor device in which a metal silicide film is formed on an upper surface of silicon wiring to lower resistance of the wiring with high reproducibility.

According to one aspect of the present invention, there is provided a method for manufacturing a semiconductor device, comprising the steps of: forming a wiring comprising silicon on a surface of a semiconductor substrate; covering part of the wiring with a resist pattern; implanting ions into the wiring using the resist pattern as a mask; removing the resist pattern; removing a surface layer of the wiring to a depth of at least 5 nm to thin the wiring; and forming a metal silicide film on a surface of the wiring by causing reaction between a surface layer of the wiring of which thickness is thus reduced and a refractory metal which reacts with silicon to form silicide.

According to another aspect of the present invention, there is provided a method for manufacturing a semiconductor device, comprising the steps of: forming wiring comprising silicon on a surface of a semiconductor substrate; covering part of the wiring with a resist pattern; implanting ions into the wiring using the resist pattern as a mask; removing the resist pattern; oxidizing the wiring beginning an upper surface thereof up to a depth thereof; removing an oxidized section of the wiring oxidized in the oxidizing step and thereby thinning the wiring; and forming a metal silicide film on a surface of the wiring by causing reaction between a surface section of the wiring of which thickness is thus reduced and a refractory metal which reacts with silicon to form silicide.

In the ion implantation, there possibly occurs a case in which an edge section of the resist pattern is sputtered by the ion beam and carbon included in the resist pattern enters a surface of the wiring. Before the silicide reaction takes place, the carbon in the surface layer can be removed when the surface layer of the wiring is removed. This resultantly prevents deterioration of the silicide reaction due to the carbon in the surface layer of the wiring.

### BRIEF DESCRIPTION OF THE DRAWINGS

FIG. 1A is a plan view of a semiconductor device manufactured in a first embodiment of a semiconductor manufacturing method of the present invention and FIG. 1B is a cross-sectional view of the semiconductor device of FIG. 1A.

FIGS. 2A to 2E are cross-sectional diagrams of a substrate to explain an embodiment of a semiconductor manufacturing method of the present invention.

FIG. 3 is a graph showing a relationship between thickness of a silicon oxide film formed by oxidizing silicon wiring and the number of positions of insufficient silicide reaction.

### DETAILED DESCRIPTION OF THE PREFERRED EMBODIMENTS

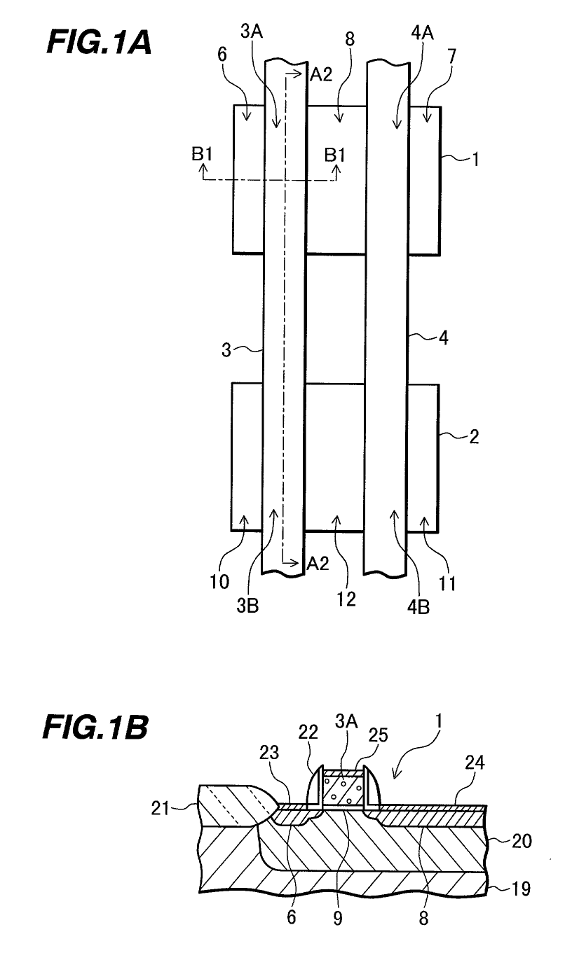

FIG. 1A shows a semiconductor device manufactured in a first embodiment of a semiconductor manufacturing method of the present invention in a plan view. A field oxide layer formed on a surface of a silicon substrate defines active regions 1 and 2. The active regions 1 and 2 are respectively placed in an n-type well and a p-type well. Each of wiring 3 and wiring 4 disposed in parallel with each other intersects the active regions 1 and 2.

Sections of the wirings 3 and 4 intersecting the active region I serve as gate electrodes 3A and 4A, respectively. Sections of the wirings 3 and 4 intersecting the active region 2 serve as gate electrodes 3B and 4B, respectively. An area of the active region 1 is divided by the gate electrodes 3A and 4A into source regions 6 and 7 and a drain region 8. A region sandwiched by the gate electrodes 3A and 4A is the drain region 8. Similarly, an area of the active region 2 is divided by the gate electrodes 3B and 4B into source regions 10 and 11 and a drain region 12.

FIG. 1B shows a cross-sectional view along one-dot-chain line B1-B1 of FIG. 1A. On a surface of a silicon substrate 20, a field oxide layer 21 is formed to define an active region 1. The active region 1 is disposed in an n-type well 20. A gate insulating film 9 and a gate electrode 3A are formed on a partial surface of the active region 1 in this order. On a sidewall of the gate electrode 3A, a sidewall spacer 22 is formed. The sidewall spacer 22 has a two-layered structure including a silicon oxide layer and a silicon nitride layer.

In a surface layer of the substrate on both sides of the gate electrode 3A, a p-type source region 6 and a p-type drain region 8 are respectively formed. The source and drain regions 6 and 8 have lightly doped drain structure. Cobalt silicide films 23, 24, and 25 are formed on surfaces of the source region 6, the drain region 8, and the gate electrode 3A, respectively.

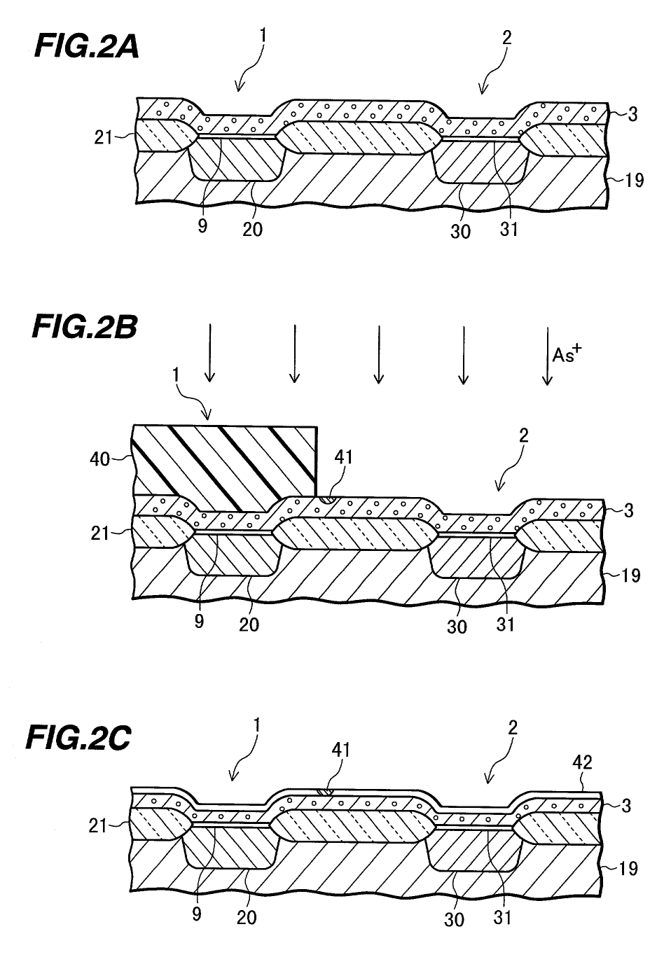

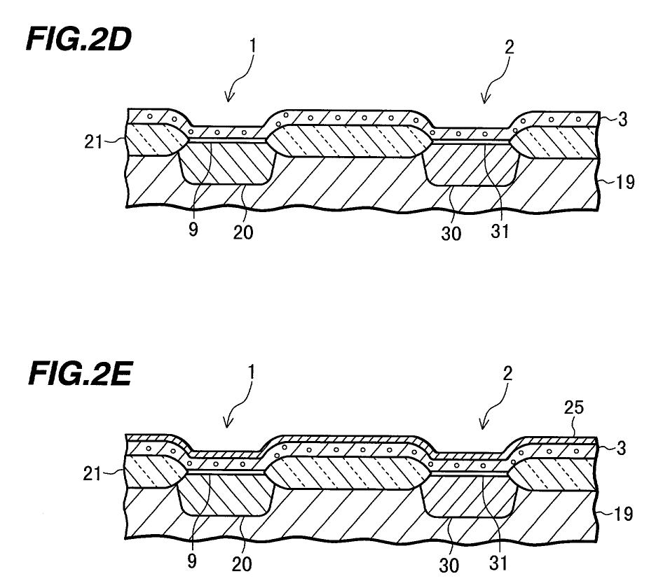

Referring to FIGS. 2A to 2E, description will be given of an embodiment of the semiconductor device manufacturing method. FIGS. 1A and 1B will be referred to in the description when necessary. Each figure shown in FIGS. 2A to 2E corresponds to a cross section along one-dot-chain line A2-A2 of FIG. 1A.

As shown in FIG. 2A, an n-type well 20 and a p-type well 30 are formed in a surface layer of a silicon substrate 19. A field oxide film 21 is then formed using a local oxidation of silicon (LOCOS) to define an active region 1 in the n-type well 20 and an active region 2 in the p-type well 30. The field oxide film 21 is, for example, 300 nm thick. By thermally oxidizing a surface of the silicon substrate 19, a gate oxide film 9 is formed on a surface of the active region 1 and a gate oxide film 31 is formed on a surface of the active region 2. The field oxide films 9 and 31 are, for example, 10 nm thick.

A polycrystalline silicon film of 180 nm thick is deposited on the overall surface of the silicon substrate 19. The polycrystalline silicon film is then patterned to form the wiring 3 shown in FIG. 1A.

As shown in FIG. 2B, the active region 1 is covered with a resist pattern 40. Using the wiring 3 and the resist pattern 40 as a mask, ions of arsenic (As⁺) are implanted in a surface layer of the substrate in the active region 2 under a condition of acceleration energy of 10 keV and a dose of 5×10¹³ cm⁻². In the operation, a sidewall of the resist pattern 40 is sputtered by the ion beam and carbon atoms in the resist pattern are scattered. Part of the scattered carbon atoms enter the wiring 3 and form a region 41 containing carbon atoms in the vicinity of an edge of the resist pattern 40.

The present inventor has detected this phenomenon by relating a defective metal silicide position to the position of the resist pattern 40. Since the resist pattern 40 has already been removed before the silicide reaction, it will not be ordinarily conducted to relate the defective metal silicide position to the resist pattern 40.

After the arsenic ion implantation, the resist pattern 40 is removed. Covering the active region 2 with a resist pattern, boron ions (B⁺) are implanted in a surface layer of the active region 1. After the boron ion implantation, the resist pattern is removed. Since a boron ion is smaller in a mass number than an arsenic ion, the boron ion beam less sputters the resist pattern than the arsenic ion beam.

By the ion implantation, the lightly doped regions of the source regions 6, 7, 10, and 11 and the drain regions 8 and 12 are formed.

Next, a sidewall spacer 22 shown in FIG. 1B is formed on a sidewall of the wiring 3. Description will be briefly given of a method of forming the sidewall spacer 22.

A 20 nm thick silicon oxide film is deposited on the overall surface of the silicon substrate 19, and then a 150 nm thick silicon nitride film is deposited on the silicon oxide film. The silicon oxide film and the silicon nitride film are formed by chemical vapor deposition (CVD). Anisotropic etching is performed on these films such that a sidewall spacer 22 remains on the sidewall of the wiring 3 (the gate electrode 3A of FIG. 1B).

Returning to FIG. 2B, after forming a resist pattern like the resist pattern 40 on the substrate 19, arsenic ions are implanted in active region 2 under a condition of an acceleration energy of 40 keV and a dose of 2×10¹⁵ cm⁻². Also in the ion implantation, the carbon containing region 41 is possibly formed. Similarly, boron ions are implanted in active region 1 under a condition of acceleration energy of 8 keV and a dose of 2×10¹⁵ cm⁻². Resultantly, the source regions 6, 7, 10, and 11 and the drain regions 8 and 12 are formed.

As shown in FIG. 2C, a surface of the wiring 3 is oxidized to form a 10 nm thick silicon oxide film 42. The carbon containing region 41 is merged into the silicon oxide film 42. The thermal oxidation is conducted using a rapid thermal processing (RTP) apparatus under a condition of an oxygen gas flow rate of 12 liters per minute, a hydrogen gas flow rate of 6 liters per minute, a substrate temperature of 1100° C., and an oxidation time of 20 seconds. Hydrogen atoms react with oxygen atoms on the substrate, and wet oxidation of silicon is performed. Since the heating period of time is short, the thermal treatment rarely exerts influence on the impurity concentration distribution formed by the processes up to this point.

As shown in FIG. 2D, the silicon oxide film 42 is removed using hydrogen fluoride. The carbon containing region 41 is also removed together therewith. The sidewall spacer 22 of FIG. 1B has a surface of silicon nitride and hence is hardly etched.

As shown in FIG. 2E, a cobalt silicide film 25 is formed on an upper surface of the wiring 3. Description will now be given of a method of forming the cobalt silicide film 25. A 10 nm thick cobalt (Co) film and a 30 nm thick titan nitride (TiN) film are deposited on the overall surface of the silicon substrate 19 by sputtering. In a nitrogen gas atmosphere, thermal treatment is performed for 30 seconds at 500° C. As a result of reaction between the wiring 3 and the cobalt film, a cobalt silicide film 25 is formed. The cobalt film which did not react with the wiring 3 and the titan nitride film are removed in a wet process using a mixture including sulfuric acid and hydrogen peroxide.

In the process to form the cobalt silicide film 25, the cobalt silicide films 23 and 24 are simultaneously formed on the source region 6 and the drain region 8, respectively.

According to the embodiment, in the process of FIG. 2E, the carbon containing region 41 of FIG. 2B is removed before the silicide reaction takes place. Carbon atoms contained in the silicon layer hinder the silicide reaction. In the region in which the carbon containing region 41 exists, the silicide reaction cannot be sufficiently achieved, and hence the cobalt silicide film 25 of a desired thickness cannot be formed. Since the carbon containing region 41 is beforehand removed in the embodiment, the cobalt silicide layer 25 can be uniformly formed on the upper surface of the wiring 3.

In the embodiment, the silicon oxide film 42 of FIG. 2C has a thickness of 10 nm. Description will next be given of a result of evaluation of silicide reaction when the silicon oxide film 42 has a thickness less than 10 nm.

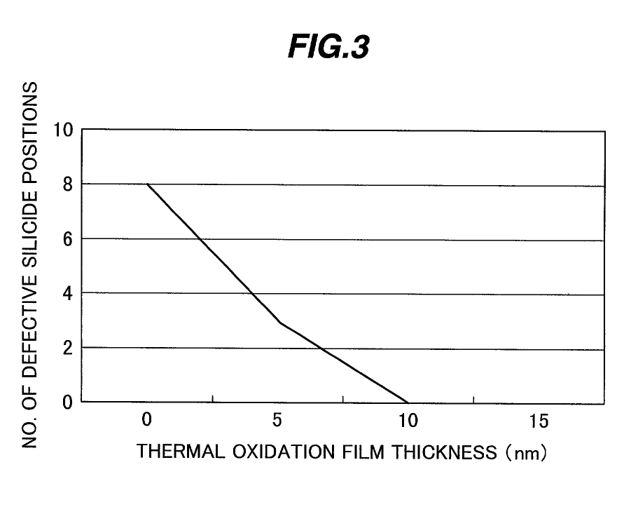

FIG. 3 shows a relationship between the thickness of the silicon oxide film 42 and the number of defective silicide positions in a graph. The abscissa represents the thickness of the silicon oxide film 42 in unit of nm and the ordinate represents the number of defective silicide positions. At an intersection between the wiring 3 of FIG. 2B and the resist pattern 40, a defective silicide position may take place. In this case, there are 20 intersections between the wiring 3 and the resist pattern 40. In the experiments for assessment or evaluation, the condition is not optimized for the silicide reaction. Therefore, the number of defective suicide positions is more than the number of defective silicide positions which will result when the condition is optimized for the silicide reaction.

According to FIG. 3, no silicide defective position appears when the thickness of the silicon oxide film 42 is 10 nm or more. It can be considered that when the condition for the silicide reaction is optimized, the number of suicide defective positions can be sufficiently minimized even if the thickness of the silicon oxide film 42 is 5 nm. Therefore, it is desired to set the thickness of the silicon oxide film 42 to 5 nm or more.

In the embodiment above, the carbon containing region 41 of FIG. 2B is removed through the oxidation using an RTP and wet etching. The carbon containing region 41 can be removed by dry etching with CF₄ gas or the like. However, secondary contamination of the silicon wiring 3 takes place by carbon atoms contained in the etching gas in this method. According to the embodiment, since the carbon containing region 41 is removed through the clean thermal oxidation and wet etching, the secondary contamination of the silicon wiring 3 can be prevented.

In the embodiment, wet oxidation is employed to oxidize the wiring 42 using the RTP apparatus in the process shown in FIG. 2C. However, another method may also be used. For example, the substrate may be dipped into an oxidizing agent or an electric furnace may be used in place of the RTP apparatus.

In the embodiment, although the cobalt suicide film 25 is formed on the silicon wiring, a similar advantage can also be obtained by forming a film of silicide of another refractory metal, for example, titan suicide (TiSi) on the silicon wiring.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A method for manufacturing a semiconductor device, comprising the steps of:
forming a wiring comprising silicon on a surface of a semiconductor substrate;
covering part of the wiring with a resist pattern;
implanting ions into the wiring using the resist pattern as a mask;
removing the resist pattern;
removing a surface layer of the wiring to a depth of at least 5 nm to thin the wiring; and
forming a metal silicide film on a surface of the wiring by causing reaction between a surface layer of the wiring of which thickness is thus reduced and a refractory metal which reacts with silicon to form silicide.

2. A method for manufacturing a semiconductor device according to claim 1, wherein the metal silicide forming step comprises the steps of:
depositing a metallic film comprising a refractory metal which reacts with silicon to form silicide, on a surface of the wiring; and
forming a metal silicide layer on an interface between the wiring and the metallic film by causing reaction therebetween.

3. A method for manufacturing a semiconductor device according to claim 1, wherein the wiring thinning step comprises the steps of:
oxidizing the wiring beginning an upper surface thereof up to a depth thereof; and
removing an oxidized section of the wiring oxidized in the oxidizing step.

4. A method for manufacturing a semiconductor device according to claim 1, wherein the metal is cobalt.

5. A method for manufacturing a semiconductor device, comprising the steps of:
forming wiring comprising silicon on a surface of a semiconductor substrate;
covering part of the wiring with a resist pattern;
implanting ions into the wiring using the resist pattern as a mask;
removing the resist pattern;
oxidizing the wiring beginning an upper surface thereof up to a depth thereof;
removing an oxidized section of the wiring oxidized in the oxidizing step and thereby thinning the wiring; and
forming a metal silicide film on a surface of the wiring by causing reaction between a surface section of the wiring of which thickness is thus reduced and a refractory metal which reacts with silicon to form silicide.

6. A method for manufacturing a semiconductor device according to claim 5, wherein the metal silicide forming step comprises the steps of:
depositing a metallic film comprising a refractory metal which reacts with silicon to form silicide, on a surface of the wiring; and
forming a metal silicide layer on an interface between the wiring and the metallic film by causing reaction therebetween.

7. A method for manufacturing a semiconductor device according to claim 5, wherein the oxidation depth to oxidize the wiring is at least 5 nm, the oxidation depth being less than a thickness of the wiring.

8. A method for manufacturing a semiconductor device according to claim 5, wherein the refractory metal is cobalt.
